(19) United States
(12) Patent Application Publication
(10) Pub. No.: US 2010/0148357 A1
(43) Pub. Date: Jun. 17, 2010

(54) METHOD OF PACKAGING INTEGRATED CIRCUIT DIES WITH THERMAL DISSIPATION CAPABILITY

(75) Inventors: Liyu Yang, Chandler, AZ (US); Scott M. Hayes, Chandler, AZ (US); Lizabeth Ann A. Keser, Chandler, AZ (US); George R. Leal, Cedar Park, TX (US)

Correspondence Address: MESCHKOW & GRESHAM, P.L.C., 7250 NORTH SIXTEENTH STREET, SUITE 318, PHOENIX, AZ, 85020-5279, US

(73) Assignee: Freescale Semiconductor, Inc., Austin, TX (US)

(21) Appl. No.: 12/335,638

(22) Filed: Dec. 16, 2008

(51) Int. Cl. H01L 23/34; H01L 21/00; H01L 23/373; H01L 21/50

(52) U.S. Cl. 257/713; 438/107; 257/E23.106; 257/E21.499

(57) ABSTRACT

A method (20) of packaging integrated circuit dies (70) includes obtaining (22) a heat spreader substrate (24) having a top surface (38) with cavities (30) formed therein, each of the cavities (30) having a cavity floor (44). A surface (74) of each die (70) is attached (66) to one of the cavity floors (44) such that a surface (72) of each die (70) and the top surface (38) of the substrate (24) are coplanar. Build-up layers (88) with electrical interconnects (97) are formed (86) over the surface (72) of each die (80) and the surface (38) of the substrate (24) to form a panel (68) of IC dies (70). Following formation of the build-up layers (88), the panel (68) is separated (108) into multiple integrated circuit packages (28), each including electrical interconnects (97), a die (70), and the substrate (24) for dissipating heat away from the die (70) during operation.

### TECHNICAL FIELD OF THE INVENTION

The present invention relates generally to integrated circuit (IC) packages. More specifically, the present invention relates to methodology for packaging IC dies with integral thermal dissipation capability.

### BACKGROUND OF THE INVENTION

Integrated circuit (IC) packaging has a significant effect on the appearance and function of end-user devices, from computers to cell phones to embedded processors. The packaging of IC devices should protect the integrated circuit die and allow coupling external to the IC die as needed. IC packaging has evolved through multiple types of packaging technologies including, for example, system in package, package on package, chips-first packaging, and so forth.

In chips-first packaging, the IC die or dies are encapsulated in a molding compound. The IC die or dies are then mounted to an inert substrate with their active surfaces face up. Interconnect circuitry can then be built above the active surface of the IC dies. The interconnect circuitry may be formed to the IC die as an integral part of the processing, thus in some embodiments eliminating the need for wire bonds, tape-automated bonds (TABs), solder bumps, or traditional substrate (leadframe or package substrate). After the interconnect circuitry is build above the active surface of the IC dies, the completed IC packages are removed from the inert substrate and sawn into discrete packages. The IC module can subsequently be incorporated into an end-user device. Accordingly this packaging technique can support high density interconnect routing and more functionality, while concurrently facilitating miniaturization, increasing yield, and decreasing cost.

There is a continually increasing demand for high power, small profile IC packages. Such IC packages can include power amplifiers, radio frequency devices, and other integrated circuit dies intended for high current or high voltage applications. Due to relatively large current conduction, the high power IC dies heat up. Unfortunately, IC dies do not perform well at elevated temperatures. Therefore, a high power IC dies needs to be cooled by removing that heat continuously and carrying the heat outside of the IC die.

The packaging of high power IC dies has been problematic because the heat generated by the individual high power IC dies in an IC package may not be effectively removed from the high power device. These problems are exacerbated with packaging technologies that provide high density interconnect routing and are intended to miniaturize devices, such as chips-first packaging. Accordingly, what is needed is an IC package and methodology for effectively packaging high power IC dies to produce IC packages with enhanced thermal dissipation capability. Such methodology should additionally mitigate problems with manufacturing precision and repeatability, while concurrently increasing yields, minimizing size, and minimizing manufacturing costs.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a flowchart of an integrated circuit (IC) die packaging process in accordance with an embodiment of the invention;

FIG. 2 shows a partial top view of a heat spreader substrate obtained in accordance with the IC die packaging process;

FIG. 3 shows a side view of the heat spreader substrate of FIG. 2:

FIG. 4 shows a side view of a heat spreader substrate in accordance with an alternative embodiment of the invention;

FIG. 5 shows a side view of a portion of a panel at a beginning stage of packaging in accordance with the IC die packaging process of FIG. 1;

FIG. 6 shows a side view of the panel shown in FIG. 5 further along in processing;

FIG. 7 shows a side view of the panel shown in FIG. 5 further along in processing; and

FIG. 8 shows a side view of IC die packages resulting from execution of the IC die packaging process of FIG. 1.

### DETAILED DESCRIPTION

Embodiments of the invention include an integrated circuit (IC) package having one or more high power IC dies integrated therein and a method for packaging IC dies with enhanced thermal dissipation capability. In an embodiment, a high power IC die may be a heat generating device such as a power amplifier, radio frequency device, or other integrated circuit die intended for high current or high voltage applications. The methodology employs a relatively low cost chips-first packaging technology incorporating a heat spreader substrate that facilitates thermal dissipation from the IC die or dies integrated therein.

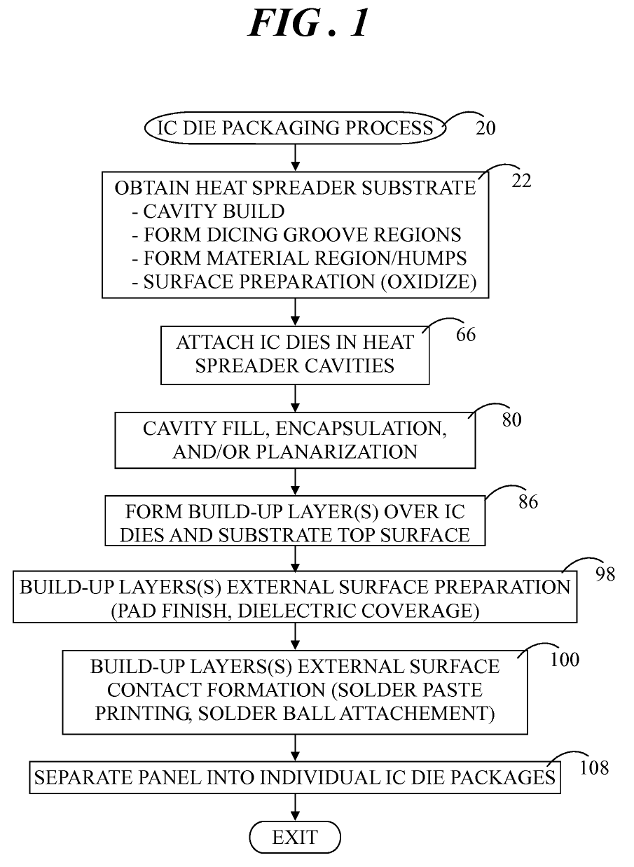

FIG. 1 shows a flowchart of an integrated circuit (IC) die packaging process 20 in accordance with an embodiment of the invention. IC die packaging process 20 describes a chips-first packaging methodology for effectively packaging IC dies. Furthermore, IC die packaging process 20 entails the incorporation of a heat spreader substrate (discussed below) that can improve heat dissipation capability, while concurrently minimizing processing costs and packaging size. Moreover, process 20 is readily and cost effectively implemented within existing packaging methodologies.

The IC die packaging process 20 is discussed in connection with the packaging of individual IC dies. However, the embodiment described applies equally to the packaging of multi-chip modules, each of which includes multiple IC dies that can perform various functions. In addition, IC die packaging process 20 is described below in connection with the fabrication of only a few IC packages for simplicity of illustration. However, it should be understood by those skilled in the art that the following process allows for concurrent manufacturing, i.e., batch processing, of a plurality of IC packages.

IC die packaging process 20 begins with a task 22. At task 22, a heat spreader substrate is obtained. In general, a heat spreader is a thermally conductive material covering or otherwise surrounding an electronic device and designed to prevent it from overheating by conducting heat away from the electronic device. In an embodiment, obtaining task 22 may entail the procurement of a heat spreader substrate. That is, a manufacturing facility performing operations of IC die packaging process 20 may obtain a heat spreader substrate provided from an external source. The external source may fabricate or otherwise procure a heat spreader substrate that includes various features, such as cavities, groove regions, material regions or humps, and surface preparation. Alternatively, obtaining task 22 may entail fabrication of the heat spreader substrate, having some or all of the aforementioned features, at the manufacturing facility performing IC die packaging process 20. These features of the heat spreader substrate will be discussed in detail below.

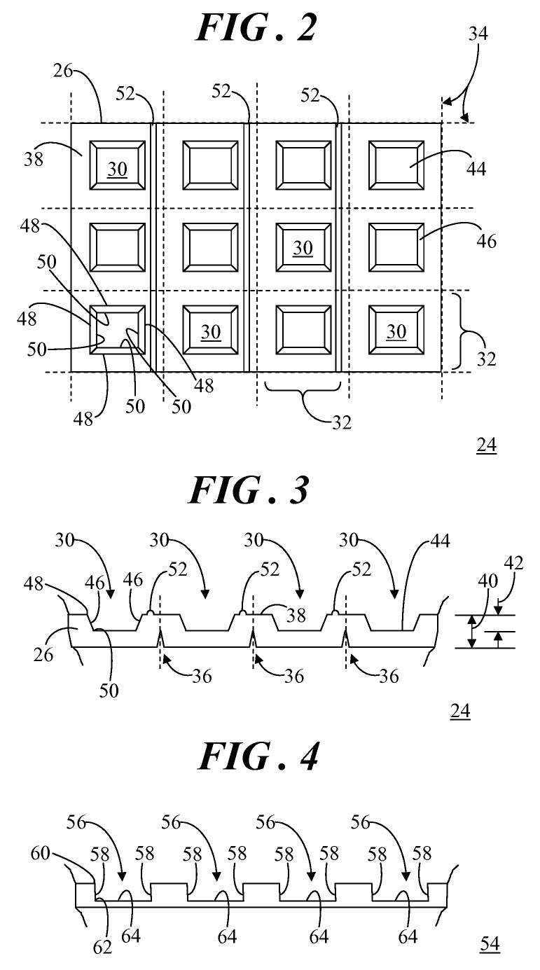

Referring to FIGS. 2 and 3 in connection with task 22, FIG. 2 shows a partial top view of a heat spreader substrate 24 obtained in accordance with IC die packaging process 20, and FIG. 3 shows a side view of heat spreader substrate 24. Heat spreader substrate 24 may be fabricated from a thermally conductive material, such as copper, aluminum, and the like.

Referring briefly to FIG. 8 in connection with FIGS. 2 and 3, heat spreader substrate 24 may be manufactured from a conductive sheet 26, such as copper, of substantial size to accommodate the concurrent manufacture of multiple IC packages 28. Conductive sheet 26 is designed and pre-patterned with a plurality of cavities 30. In the illustration of FIGS. 2 and 3, multiple portions 32 of heat spreader substrate 24 that are incorporated into IC packages 28 are distinguished by their surrounding dashed lines. The dashed lines represent a dicing pattern 34 for the larger conductive sheet 26. Through the packaging operations of process 20, a panel of IC packages 28 is formed. This panel of IC packages 28 will eventually be separated in accordance with dicing pattern 34 to form a number of individual IC packages 28.

In an embodiment, heat spreader substrate 24 may include regions of material absence aligned with dicing pattern 34. For example, heat spreader substrate 24 may include groove regions 36 corresponding to dicing pattern 34. Groove regions 36 are thinned pre-formed or pre-cut regions of heat spreader substrate 24 aligned with dicing pattern 34. The thinner material at groove regions 36 may facilitate separation of the panel of IC packages 28 (FIG. 8) into individual IC packages 28 during subsequent operations of IC packaging process 20 (discussed below). In another embodiment, the regions of material absence may be perforations through heat spreader substrate 24, i.e., discontinuous sheet material, aligned with dicing pattern 34 that can facilitate separation of the panel of IC packages 28 into individual IC packages 28 during the subsequent operations of IC packaging processes 20. Those skilled in the art will recognize that there may be still other ways for producing regions of material absence, i.e., thinner material and/or perforations, aligned with dicing pattern so as to facilitate singulation of IC packages 28.

In an embodiment, heat spreader substrate 24 may be used as a starting structure, or process carrier, for the chips-first packaging operations of IC packaging process 20, as discussed in greater detail below. The portion of heat spreader substrate 24 illustrated herein is generally rectangular in shape. However, it should be understood that conductive sheet 26 and heat spreader substrate 24 formed from it may be rectangular, circular, or another suitable shape.

Cavities 30 are formed in a top surface 38 of heat spreader substrate 24 and extend into heat spreader substrate 24. Cavities 30 do not extend through an entire thickness 40 of substrate 24. That is, cavities 30 exhibit a depth 42 that is less than thickness 40 of substrate 24. Accordingly, each of cavities 30 includes a cavity floor 44 in heat spreader substrate 24. Cavities 30 may be formed in conductive sheet 26 using a process that is suitable for thickness 40 of conductive sheet 26. Such processes include, for example, milling, stamping, drilling, or chemical etching into top surface 38 to form cavities 30.

Each of cavities 30 has side walls 46 extending from top surface 38 of heat spreader substrate 24 to cavity floor 44. In an embodiment, side walls 46 are outwardly angled such that a perimeter 48 of each of cavities 30 at top surface 38 is greater than a perimeter 50 of each of cavities 30 at cavity floor 44. The outward angle of side walls 46 accommodates equipment used to place IC dies (discussed below) in cavities 30 during later operations of IC packaging process 20.

Heat spreader substrate 24 may additionally be formed to include material regions 52 extending above top surface 38. In the illustrated embodiment, material regions 52 are generally elongated curved humps arranged on top surface 38. Material regions 52 can enhance adhesion of build-up layers formed on top surface 38 during later operations of IC packaging process 20. Alternatively, or in addition, material regions 52 may increase the stiffness of a panel formed from heat spreader substrate 24 to provide greater reliability of heat spreader substrate as a process carrier during subsequent operations of IC packaging process. As such, it should be noted that material regions 52 are offset from groove regions 36 so that material regions 52 do not add to the thickness of heat spreader substrate 24 in the region where separation will occur, i.e., dicing pattern 34. Although material regions are illustrated as elongated, curved humps, it should be understood that material regions 52 can be various shapes and sizes, can be positioned on top surface 38 in accordance with a pre-determined design, or may be absent in some designs.

In an embodiment, cavity floors 44, top surface 38, and/or side walls 46 may be oxidized to facilitate adhesion between heat spreader substrate 24 and any die attach materials, encapsulation materials, and/or build-up layers (discussed below). For example, heat spreader substrate 24 may be a material, such as copper, that is reacted with oxygen to form an oxide coating. Alternatively, heat spreader substrate 24 may be covered or otherwise coated with an oxide coating.

Referring now to FIG. 4 in connection with task 22 of IC module packaging process 20 (FIG. 2), FIG. 4 shows a side view of a heat spreader substrate 54 in accordance with an alternative embodiment of the invention. Heat spreader substrate 54 is shown having cavities 56 with side walls 58 that are largely vertically oriented, rather than outwardly angled side walls 46 of cavities 30. That is, a perimeter 60 of each of cavities 56 at a top surface 60 of heat spreader substrate 54 is substantially equal to a perimeter 62 at a cavity floor 64 of each of cavities 56. Since IC dies (discussed below) are placed in cavities 56, this configuration of side walls 58 may allow a greater surface area of side walls 58 to reside proximate the IC dies, may offer space savings, and/or may be more straightforward to fabricate.

With reference back to FIG. 2, following task 22, IC packaging process 20 continues with a task 66. At task 66, IC dies are attached in the cavities of the particular heat spreader substrate utilized herein. This and subsequent tasks of IC packaging process 20 are discussed in connection with heat spreader substrate 24 (FIGS. 2-3). However, it should be understood that heat spreader substrate 54 (FIG. 4) or other alternative configurations of a heat spreader substrate may be utilized in connection with task 66 and the subsequent tasks of IC packaging process 20.

Referring to FIG. 5 in connection with task 66, FIG. 5 shows a side view of a portion of a panel 68 at a beginning stage of packaging in accordance with IC die packaging process 20. Panel 68 includes a portion of heat spreader substrate 24 showing four cavities 30. One of a number of IC dies 70 is attached to cavity floor 44 of each of cavities 30. In an embodiment, panel 68 includes a plurality of IC dies 70, of which only four are shown for simplicity of illustration. These IC dies 70 may be devices that have previously passed testing requirements, such as electrical, mechanical, or both (i.e., they are known good die). The present invention is discussed in connection with the packaging of individual IC dies 70. However, the present invention applies equally to the packaging of multi-chip modules, each of which includes multiple IC dies that can perform various functions.

In an embodiment, each of IC dies 70 includes a surface, referred to herein as an active surface 72, and another surface, referred to herein as an inactive surface 74. Active surface 72 refers to that side of each of IC dies 70 having bond pads, or contacts (not visible), that provide input and output with other components external to IC dies 70. Conversely, inactive surface 74 does not have bond pads or contacts for electrical interconnection with other components. At task 66, each cavity floor 44 may be coated with a die attachment adhesive, high thermal conductivity epoxy, solder, or another die attach material. One of IC dies 70 is placed in each of cavities 30 with inactive surface 74 face down on the adhesive coating.

In an embodiment, depth 42 of cavities 30 is configured to accommodate IC dies 70 such that upon attachment of inactive surface 74 to cavity floors 44, active surface 72 is substantially coplanar with top surface 38 of heat spreader substrate 24. This coplanar configuration facilitates the fabrication of build-up layers in the subsequent tasks of IC packaging process 20.

It should be noted that an outer perimeter 76 of each of IC dies 70 is smaller than perimeter 50 of each of cavities 30. Thus, cavities 30 are configured to accommodate generally flat placement of IC dies 70 on respective cavity floors 44, but are configured to be only slightly larger than outer perimeter 76 of IC dies 70 so as to limit the possible drifting, or movement, of IC dies 70 during subsequent processing operations. However, the smaller configuration of IC dies 70 relative to cavities 30 results in a gap 78 being formed between side walls 46 of cavities 30 and outer perimeter 76 of IC dies 70.

In conventional chips-first processing, a release film is secured to a support substrate and individual IC dies are attached to the support substrate, also referred to as a process carrier, with their active surfaces face down on the release film. The IC die or dies are then at least partially encapsulated in a molding compound. Following encapsulation, the IC die or dies are released from the support substrate and are mounted to another substrate with their active surfaces face up. Interconnect circuitry can then be built above the active surface of the IC dies. In the embodiment discussed herein, the die attach, encapsulation, and release operations are not needed because heat spreader substrate 24 functions as the process carrier. Thus, savings is achieved in terms of less process steps and lower manufacturing costs.

With reference back to FIG. 1, following task 66, IC packaging process 20 continues with a task 80. At task 80, cavity fill, encapsulation, and planarization operations may be selectively performed to ensure that active surface 72 of each of IC dies 70 is coplanar with top surface 38 of heat spreader substrate 24 and/or to fill gaps 78.

Referring to FIG. 6 in connection with task 80, FIG. 6 shows a side view of panel 68 shown in FIG. 5 further along in processing. As illustrated in FIG. 6, gaps 78 around each of IC dies 70 have been filled with an encapsulant 82. Exemplary encapsulants 82 include, but are not limited to, a high thermal conductivity encapsulant and a silica-filled epoxy molding compound, although other known and upcoming encapsulants 82 may be utilized. The filling of gaps 78 results in a build-up surface 84 of panel 68, with the exception of material regions 52, being substantially planar. In additional and alternative operations, build-up surface 84 of panel 68 may undergo surface planarity processing by, for example, applying a thin film onto build-up surface 84 using a spin coating technique. In another embodiment, gaps 78 may not be filled with a separate encapsulant 82. Rather, gaps 78 may be filled with another suitable material when panel 68 undergoes surface planarity processing.

With reference back to FIG. 1, following task 80, IC packaging process 20 continues with a task 86. At task 86, build-up layers are formed over build-up surface 84, including active surface 72 of IC dies 70 and top surface 38 of heat spreader substrate 24. More specifically, panel 68 undergoes processing to form electrical interconnects for signals, power, and ground lines to be routed between external elements and the bond pads on active surface 72 of each of IC dies 70 through the construction of build-up layers.

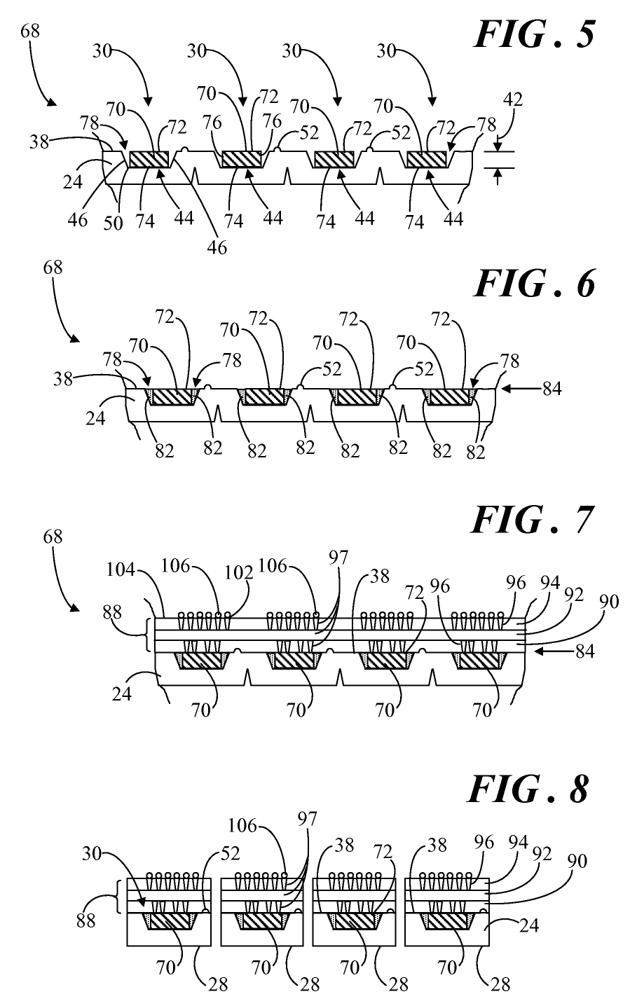

Referring to FIG. 7 in connection with task 86, FIG. 7 shows a side view of panel 68 shown in FIG. 5 further along in processing. Panel 68 includes one or more dielectric material layers and one or more overlying circuit metal layers, i.e., electrically conductive material layers, within which traces, or electrical interconnects, may be formed. Electrical interconnects may be routed or redistributed among the one or more dielectric and electrically conductive material layers to minimize the area of each of IC modules 28 (FIG. 8). The dielectric and electrically conductive material layers are collectively referred to herein as build-up layers 88.

Routing may be performed using standard silicon manufacturing equipment. These processing steps can include the deposition of a dielectric insulating layer 90 typically formed from a spin-coated photoimageable dielectric and patterned using batch process of lithography. A next processing step can include the deposition of an electrically conductive, e.g., copper metallization, layer 92 by electroplating techniques within which traces may be formed, followed by another dielectric insulating layer 94, and so forth. In addition, via-holes may be formed by patterning and etching the one or more dielectric layers (e.g., layers 90 and 94). The via-holes are then filled with a conductive material to form conductive vias 96 that may be used to interconnect with contacts or traces in, for example, the overlying or underlying electrically conductive layer 92. The traces formed in electrically conductive layer 92 and the interconnecting conductive vias 96 that form the routing between the external elements and the bond pads on active surface 72 of each of IC dies 70 are generally referred to herein as electrical interconnects 97.

The number of individual material layers in build-up layers 88 is dictated by the package size, land grid array or ball grid array pitch requirement, input/output count, power and ground requirements, and routing design rules. The resulting package (e.g., IC packages 28 shown in FIG. 8) including build-up layers 88 is sometimes referred to as a redistributed chip package (RCP) because electrical interconnects 97 are routed or redistributed among the one or more layers (e.g., layers 90, 92, 94) within build-up layers 88 to minimize the area of the package. Consequently, in the embodiment shown, no wirebonding or traditional substrate (leadframe or package substrate) is needed to form an RCP thus increasing yield and decreasing cost.

With reference back to FIG. 1, following task 86, IC packaging process 20 continues with a task 98. At task 98, the external surface of build-up layers 88 (FIG. 7) is prepared for contact formation. Surface preparation can entail the conventional processes of pad finish, dielectric coverage, and so forth.

Next a task 100 is performed. At task 100, contact formation on the external surface of build-up layers 88 is performed. Contact formation can entail the conventional processes of solder paste printing or solder ball attachment. Referring momentarily to FIG. 7, electrical interconnects 97, represented by electrically conductive layer 92 and conductive vias 96, connect bond pads (not visible) on active surface 72 of each of IC dies 70 to pads 102 placed on an exterior surface 104 of build-up layers 88. Pads 102 can then be soldered or can be provided with a solder finish for land grid array (LGA) or solder balls 106 for ball grid array (BGA). Solder finish material includes, but is not limited to, a nickel-gold (NiAu) alloy, copper organic solderability preservative (Cu OSP), nickel-palladium alloy (NiPd), and the like.

With reference back to FIG. 1, following task 100, a task 108 is performed. At task 108, panel 68 is separated into individual IC packages 28. For example, panel 68 may be cut, or diced, per convention in accordance with dicing pattern 34 (FIGS. 2-3) to provide individual IC packages 28, each of which includes a portion of heat spreader substrate 24, at least one of IC dies 70, and a section of electrical interconnects 97. IC die packaging process 20 exits following task 108.

FIG. 8 shows a side view of IC packages 28 resulting from execution of IC die packaging process 20 (FIG. 2). As shown, each of IC packages 28 includes one of IC dies 70 residing in one of cavities 30 formed in heat spreader substrate 24. Build-up layers, for example, dielectric insulating layers 90 and 94 and electrically conductive layer 92, are formed over active surface 72 of each of IC dies 70 and top surface 38 of heat spreader substrate 24 to form electrical interconnects 97. Finally, solder balls 106 may be formed on exterior surface 104 of build-up layers 88. At this point IC packages 28 can be processed in accordance with known methodology in preparation for their incorporation into electronic devices.

It should be understood that IC packages 28 and the particular components of IC packages 28 are presented for illustrative purposes. Those skilled in the art will recognize the IC packages 28 can take many forms and can include more or less devices than those shown, including more dies per package. For example, in an embodiment, a multiple IC die package may have more than one cavity 30, each cavity 30 having one of IC dies 70 residing therein. In another embodiment, a multiple IC die package may have one cavity 30, with more than one IC die 70 residing therein. Of course, in a multiple IC die package, IC dies 70 may not be identical, but may instead have different functions in accordance with the particular design of the multiple IC die package.

Embodiments of the invention entail an IC package and a method of packaging IC dies so as to enhance their thermal dissipation capability. Packaging methodology calls for the inclusion of an integral heat spreader substrate with preformed cavities. The IC dies are attached to the heat spreader substrate with their corresponding active surfaces arranged face up to form a panel of IC dies. Build-up layers are formed overlying the active surfaces of the IC dies and the panel is separated to produce individual IC packages, each of which includes an integral heat spreader substrate. Such packaging methodology is especially suitable for packaging high power IC dies to produce IC packages in miniaturized form with enhanced thermal dissipation capability. Placement of the IC dies in the cavities mitigates problems associated with IC die drifting, or movement, during subsequent processing operations. Moreover, the heat spreader substrate functions as a process carrier during packaging. Since the IC dies are not subsequently detached from the heat spreader substrate, operations of the prior art such as die attach, encapsulation, and IC die release are not needed. Accordingly, savings is achieved in terms of less process steps, thereby mitigating problems associated with manufacturing precision and repeatability, while concurrently increasing yields, minimizing size, and lowering manufacturing costs.

Although the preferred embodiments of the invention have been illustrated and described in detail, it will be readily apparent to those skilled in the art that various modifications may be made therein without departing from the spirit of the invention or from the scope of the appended claims.

What is claimed is:

1. A method of packaging an integrated circuit (IC) die with thermal dissipation capability, said IC die having a first surface and a second surface, and said method comprising:
obtaining a heat spreader substrate having a cavity formed in a top surface of said substrate, said cavity including a cavity floor;
attaching said second surface of said IC die to said cavity floor such that said first surface of said IC die and said top surface of said heat spreader substrate are substantially coplanar; and
forming electrical interconnects over said first surface of said IC die, wherein an IC package includes said heat spreader substrate, said IC die, and said electrical interconnects.

2. A method as claimed in claim 1 wherein said IC die is one of multiple IC dies, said heat spreader substrate includes multiple ones of said cavity each having said cavity floor, and:
said attaching operation comprises attaching each of said multiple IC dies to said cavity floor of said multiple ones of said cavity;
said forming operation forms said electrical interconnects over said first surface of said each of said multiple IC dies to form a panel of said multiple IC dies; and
following said forming operation, said method further includes separating said panel to form individual IC packages each including a portion of said heat spreader substrate, at least one of said multiple IC dies, and a section of said electrical interconnects.

3. A method as claimed in claim 2 wherein:
said obtaining operation obtains said heat spreader substrate having regions of material absence aligned with a predetermined dicing pattern for said panel; and
said separating operation separates said panel at said regions to form said individual IC packages.

4. A method as claimed in claim 1 wherein said obtaining operation obtains said heat spreader substrate with said cavity exhibiting a depth that is less than a thickness of said heat spreader substrate.

5. A method as claimed in claim 1 wherein said obtaining operation obtains said heat spreader substrate with said cavity having side walls extending from said top surface of said substrate to said cavity floor, each of said side walls being outwardly angled such that a first perimeter of said cavity at said top surface is greater than a second perimeter of said cavity at said cavity floor.

6. A method as claimed in claim 1 wherein said obtaining operation obtains said heat spreader substrate with said cavity having side walls extending from said top surface of said substrate to said cavity floor, each of said side walls being substantially vertically oriented such that a first perimeter of said cavity at said top surface is substantially equivalent to a second perimeter of said cavity at said cavity floor.

7. A method as claimed in claim 1 wherein:
said obtaining operation obtains said heat spreader substrate with material regions extending above said top surface of said substrate; and
said forming operation forms said electrical interconnects through a dielectric material, said material regions facilitating adhesion of said dielectric material to said top surface of said heat spreader substrate.

8. A method as claimed in claim 1 wherein said heat spreader substrate is formed from a metal panel, and said obtaining operation obtains said heat spreader substrate that is oxidized prior to attachment of said IC die to said cavity floor.

9. A method as claimed in claim 1 wherein a first perimeter of said IC die is smaller than a second perimeter of said cavity such that a gap is formed between side walls of said cavity and said first perimeter of said IC die, and said method further comprises filling said gap with an encapsulant.

10. A method as claimed in claim 1 wherein said forming operation comprises forming build-up layers over said top surface of said substrate and said first surface of said IC die, said build-up layers including a dielectric material and an electrically conductive material, said electrical interconnects being formed in said build-up layers.

11. An integrated circuit (IC) package comprising:
a heat spreader substrate having a cavity formed in a top surface of said substrate, said cavity including a cavity floor;
an IC die having a first surface and a second surface, said second surface of said IC die being attached to said cavity floor such that said first surface of said IC die and said top surface of said heat spreader substrate are substantially coplanar; and
build-up layers formed over said top surface of said heat spreader substrate and said first surface of said IC die, said build-up layers including a dielectric material and an electrically conductive material, said build-up layers including electrical interconnects formed therein.

12. An IC package as claimed in claim 11 wherein said cavity exhibits a depth that is less than a thickness of said heat spreader substrate.

13. An IC package as claimed in claim 11 wherein said cavity comprises side walls extending from said top surface of said heat spreader substrate to said cavity floor, each of said side walls being outwardly angled such that a first perimeter of said cavity at said top surface is greater than a second perimeter of said cavity at said cavity floor.

14. An IC package as claimed in claim 11 wherein said heat spreader substrate includes material regions extending above said top surface of said substrate, said material regions facilitating adhesion of said build-up layers to said top surface of said substrate.

15. An IC package as claimed in claim 11 wherein said heat spreader substrate comprises a metal panel, said metal panel being oxidized prior to attachment of said IC die to said cavity floor.

16. An IC package as claimed in claim 11 wherein said IC die exhibits a first perimeter, said cavity exhibits a second perimeter, said first perimeter being smaller than said second perimeter such that a gap is formed between side walls of said cavity and said first perimeter of said IC die, and said IC package further comprises an encapsulant positioned in said gap.

17. A method of packaging multiple integrated circuit (IC) dies with thermal dissipation capability, each of said multiple IC dies having a first surface and a second surface, and said method comprising:
obtaining a heat spreader substrate having multiple cavities formed in a top surface of said substrate, each of said cavities including a cavity floor;
for said each of said multiple IC dies, attaching said second surface to said cavity floor in one of said cavities such that said first surface of said each IC die and said top surface of said heat spreader substrate are substantially coplanar;
forming build-up layers over said first surface of said each of said multiple IC dies, said build-up layers including a dielectric material and an electrically conductive material, said forming operation forming electrical interconnects over said first surface of said each of said multiple IC dies to form a panel of said multiple IC dies; and
following said forming operation, separating said panel of said multiple IC dies to form individual IC packages each including a portion of said heat spreader substrate, at least one of said IC dies, and a section of said electrical interconnects.

18. A method as claimed in claim 17 wherein:
obtaining operation obtains said heat spreader substrate having regions of material absence aligned with a predetermined dicing pattern for said panel; and
said separating operation separates said panel at said regions to form said individual IC packages.

19. A method as claimed in claim 17 wherein said obtaining operation obtains said heat spreader substrate with each of said cavities having side walls extending from said top surface of said substrate to said cavity floor, each of said side walls being outwardly angled such that a first perimeter of said each cavity at said top surface is greater than a second perimeter of said each cavity at said cavity floor.

20. A method as claimed in claim 17 wherein a first perimeter of said each of said multiple IC dies is smaller than a second perimeter of said each of said cavities such that a gap is formed between side walls of said each cavity and said first perimeter of said each of said multiple IC dies, and said method further comprises filling said gap with an encapsulant prior to forming said build-up layers.
